(19) United States
(12) Patent Application Publication
(10) Pub. No.: US 2018/0005797 A1
(43) Pub. Date: Jan. 4, 2018

(54) SCANNING ELECTRON MICROSCOPE

(71) Applicant: NGR Inc., Yokohama (JP)

(72) Inventors: Makoto KATO, Yokohama (JP); Susumu TAKASHIMA, Yokohama (JP); Kazufumi KUBOTA, Yokohama (JP); Kaoru ZENYOUJI, Yokohama (JP); Yuichiro YAMAZAKI, Yokohama (JP)

(21) Appl. No.: 15/196,507

(22) Filed: Jun. 29, 2016

(51) Int. Cl. H01J 37/244; H01J 37/22; H01J 37/28

(52) U.S. Cl. CPC H01J 37/244; H01J 37/28; H01J 37/222; H01J 2237/24564; H01J 2237/24475

(57) ABSTRACT

A scanning electron microscope including: an electron beam source for generating a primary electron beam; an electron optical system configured to direct the primary electron beam to a specimen while focusing and deflecting the primary electron beam; and an energy analyzing system capable of performing parallel detection of an energy spectrum of back-scattered electrons emitted from the specimen is disclosed. The energy analyzing system includes: a Wien filter configured to separate the back-scattered electrons from a beam axis and analyze energies of the back-scattered electrons; and an array detector configured to detect the back-scattered electrons that have passed through the Wien filter. The Wien filter includes a plurality of electromagnetic poles, center-side ends of the plurality of electromagnetic poles have tapered surfaces, respectively, and the tapered surfaces form an exit of the Wien filter through which the back-scattered electrons pass out.

### BACKGROUND

The present invention relates to a scanning electron microscope, and more particularly to a Wien filter which can analyze energies of back-scattered electrons emitted from a specimen.

A scanning electron microscope for the purpose of observing semiconductor devices has been developed. With a trend toward finer and finer device patterns to be observed, multilayered structure of patterns is progressing. Under such circumstances, it is effective for the scanning electron microscope to use a high acceleration voltage capable of generating a high penetration force and to observe back-scattered electrons having appropriate energies determined depending on a depth from a surface of a specimen which is an object of the observation. For this purpose, it is necessary to freely select an energy range of the back-scattered electrons in accordance with the specimen to be observed, and to generate an image of the back-scattered electrons using only signals within such a range.

In a conventional technique, in order to analyze the energy of the back-scattered electrons, a Wien filter is used to deflect the back-scattered electrons from a beam axis slightly (e.g., by 10 degrees) to direct the back-scattered electrons to an energy analyzer, such as an electrostatic spherical analyzer or a magnetic-field sector analyzer, by which the energy is analyzed. Such a technique using the Wien filter to separate the back-scattered electrons, or so-called secondary electrons, from primary electrons is disclosed in U.S. Pat. No. 5,422,486 “Scanning electron beam device”. In addition, a technique using a combination of a Wien filter and an energy analyzer is disclosed in U.S. Pat. No. 6,455,848 “Particle-optical apparatus involving detection of Auger electronics”.

In the creation of the image of the back-scattered electrons with the selected energies, the energy range to be selected varies from specimen to specimen to be observed. Accordingly, it is necessary to firstly perform a rough analysis of an energy range of the back-scattered electrons which is as wide as possible, identify a narrow energy range which is useful for characterizing the specimen, and then form an image of the selected back-scattered electrons only within that energy range.

The electrostatic spherical analyzer is a typical energy analyzer for use in the analysis of the energies of the back-scattered electrons. This type of analyzer has a high energy resolution, but has a strictly limited range of energies that can be detected at a time, because this type of analyzer is configured to detect, at its outlet side, only electrons which have passed through a narrow space between electrodes. In particular, when the energy of the back-scattered electrons to be analyzed is as high as several tens keV, the interval between the electrodes should be narrow in order to avoid an increase in voltage applied to the electrodes. As a result, an energy range in which a simultaneous detection can be achieved becomes narrower. For this reason, in order to observe a spectral distribution in a wide energy range, it is necessary to perform a serial detection by sweeping a pass energy with the analyzer. Performing the serial detection entails a complicated control for obtaining a spectral distribution over an entire energy range. Moreover, it takes a long measuring time. Such circumstances are the same in other types of analyzer.

### SUMMARY OF THE INVENTION

According to an embodiment of the present invention, there is provided a scanning electron microscope comprising: an electron beam source for generating a primary electron beam; an electron optical system configured to direct the primary electron beam to a specimen while focusing and deflecting the primary electron beam; and an energy analyzing system capable of performing parallel detection of an energy spectrum of back-scattered electrons emitted from the specimen, the energy analyzing system including: a Wien filter configured to separate the back-scattered electrons from a beam axis and analyze energies of the back-scattered electrons; and an array detector configured to detect the back-scattered electrons that have passed through the Wien filter, wherein the Wien filter includes a plurality of electromagnetic poles, center-side ends of the plurality of electromagnetic poles have tapered surfaces, respectively, and the tapered surfaces form an exit of the Wien filter through which the back-scattered electrons pass out.

In an embodiment, the Wien filter is configured to be able to change strengths of quadrupole fields comprising an electric field or a magnetic field, in order to optimize energy resolution in an energy range in which an image of the back-scattered electrons is formed.

In an embodiment, the scanning electron microscope further comprises an imaging device configured to create an image using only output signals of the array detector within a preselected energy range.

According to the above-described embodiments, a parallel detection in a wide energy range can be achieved. In addition, the same energy resolution as that of a conventional energy analyzing system can be obtained.

### BRIEF DESCRIPTION OF THE DRAWINGS

FIG. 1 is a schematic view showing a basic structure of a scanning electron microscope according to an embodiment of the present invention;

FIG. 2 is a schematic view of an embodiment of a Wien filter;

FIG. 3 is a cross-sectional perspective view of the Wien filter;

FIG. 4 shows an example of a simulation result of an operation of the Wien filter; and

FIG. 5 shows an example of a simulation result of an operation of the Wien filter.

### DESCRIPTION OF EMBODIMENTS

Embodiments of the present invention will be described below with reference to the drawings.

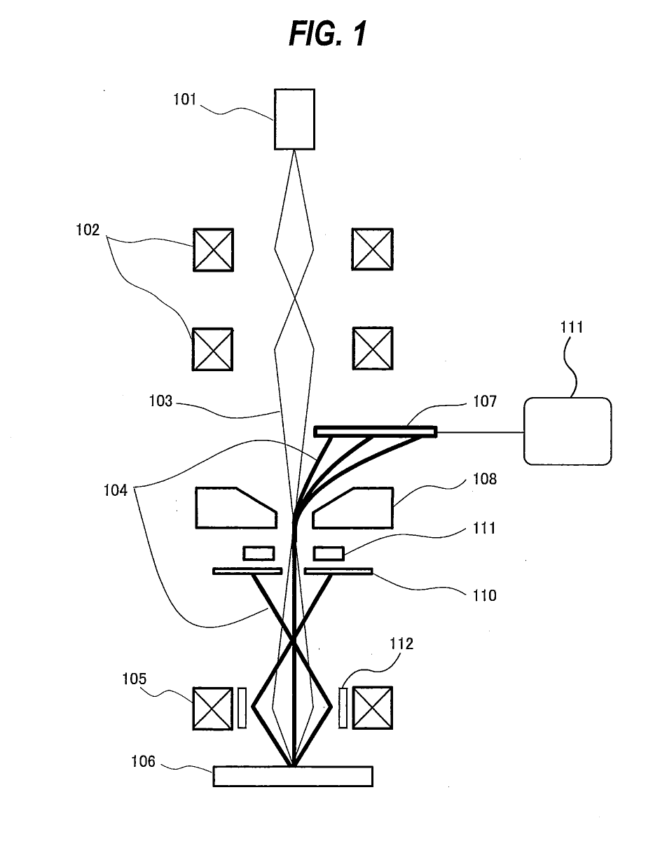

FIG. 1 is a schematic view showing a basic structure of a scanning electron microscope according to an embodiment of the present invention. In FIG. 1, an electron gun 101, serving as an electron beam source, generates a primary electron beam 103, which is firstly converged by a condenser lens system 102 composed of multiple lenses. The primary electron beam 103 passes through a Wien filter 108 and is focused by an objective lens 105 onto a specimen 106. The primary electron beam 103 is deflected by a deflector 112 so as to scan a surface of the specimen 106.

A diameter of a back-scattered electron beam 104, emitted from the specimen 106, is restricted appropriately by a back-scattered electron diaphragm 110. This back-scattered electron diaphragm 110 has an aperture which provides a light source as viewed from an energy analyzing system. The back-scattered electron beam 104 that has passed through the back-scattered electron diaphragm 110 is deflected by the Wien filter 108 in accordance with energies, and is detected by an array detector 107. This array detector 107 produces an energy spectrum of back-scattered electrons distributed in accordance with energies. An imaging device 111 selects an energy range characterizing the specimen 106 from the energy spectrum, and forms an image using only output signals of the array detector 107 within the selected energy range. This image is a targeted image of back-scattered electrons.

Generally, the Wien filter produces an electric field and a magnetic field, which intersect at right angles in a plane perpendicular to a beam axis. The Wien filter is originally used as an energy analyzer, while it is also used as a beam separator for deflecting only one of electron beams entering the Wien filter from both directions. The Wien filter used for this application may be called E×B deflector.

Operations of the Wien filter used as a beam separator in the scanning electron microscope will be described below. First, the electric field and the magnetic field are produced so as to exert forces on the primary electron beam in opposite directions so that the forces are cancelled mutually. A condition of strengths of the electric field and the magnetic field in this state is called Wien condition, which is expressed as E₁=vB₁. E₁ represents a uniform field component of the electric field in an x direction produced by the Wien filter, and has a cos θ dependence with respect to an angle of direction θ. B₁ represents a uniform field component of the magnetic field in a y direction produced by the Wien filter, and has a sin θ dependence with respect to an angle of direction θ. When electrons at a speed v enter along a z axis (i.e., the beam axis) from a direction of z<0, the electrons travel straight as they are when the electric field and the magnetic field satisfy the Wien condition. When the electrons enter along the beam axis from the opposite direction under the Wien condition, the electric field and the magnetic field exert forces on the electrons in the same direction, because the direction of force from the magnetic field is reversed. As a result, the Wien filter functions as a deflector. In this manner, the Wien filter can deflect the electron beam, which is traveling in the opposite direction, from the beam axis without affecting the primary electrons. This is the operation of the Wien filter as a beam separator.

In the meantime, the Wien filter originally has a function as an energy analyzer. From a viewpoint of the primary electron beam when the Wien filter is used as a beam separator, the electrons go straight as they are at a speed v that fulfils the Wien condition. However, electrons, having a speed different from the speed v, destroy the balance between the electric field and the magnetic field. As a result, those electrons are deflected in either positive or negative direction in the x direction. Such an action results in a generation of an energy spectrum at an outlet side of the Wien filter. This is the original function of the Wien filter working as an energy analyzer. In the case where the Wien filter is used as a beam separator, this action of energy dispersion is unnecessary. Specifically, it is ideal for the primary electron beam to simply pass as it is. However, the primary electron beam is slightly dispersed when passing through the Wien filter because the electron beam, emitted by the electron gun, generally has an energy width ΔE=0.5 eV. As a result, separation of the beam occurs on the surface of the specimen, thus causing a deterioration of an image resolution. However, this action can be avoided by forming a crossover of the primary electron beam at the center of the Wien filter. Under this condition, the dispersion of the primary electron beam is returned to zero, and therefore does not affect the resolution.

There is another problem which can occur when using the Wien filter as a beam separator. When the Wien filter forms a uniform electric field and a uniform magnetic field, the primary electron beam satisfying the Wien condition is slightly subjected to a focusing lens action in the x direction, while there is no focusing lens action in the y direction. Thus, the primary electron beam is subjected to the same action as an action on the primary electron beam when passing through a lens having astigmatism. In order to cancel this action, it is necessary to cause the Wien filter to superimpose quadrupole field components. The quadrupole fields exert different lens actions in the x direction and the y direction. Therefore, establishing good strengths of the quadrupole fields can provide a lens action which is symmetric in the x direction and the y direction (i.e., axisymmetric) in the entirety of the Wien filter. Such a lens action does not exert aberration on the primary electron beam. This condition is called stigmatic condition. The quadrupole fields that can satisfy this condition have an B₂ component having cos 2θ dependence in a case where the quadrupole fields are produced by the electric field, or have a B₂ component having sin 2θ dependence in a case where the quadrupole fields are produced by the magnetic field. Alternatively, the quadrupole fields may have the E₂ component and the B₂ component which are superimposed.

In an embodiment of the present invention, the Wien filter 108 performs the above-described operation as the beam separator. The Wien filter 108 acts as a deflector on the back-scattered electrons entering in the direction opposite to the primary electron beam. This deflecting action itself has the action of energy dispersion. In a conventional technique, a Wien filter, serving as a beam separator, has a small deflection angle, typically about 10 degrees. In this embodiment, the Wien filter 108 has electromagnetic poles each having a modified shape. Specifically, each of the electromagnetic poles has a tapered shape at an outlet side (or upper side) of the Wien filter at which the back-scattered electrons exit. This tapered shape can allow the Wien filter to achieve a large deflection angle, and can therefore enable simultaneous measurement in a wide energy range. Although a good energy resolution cannot be achieved by only this operation, this weakness can be avoided by optimizing the quadrupole fields, as discussed later.

Next, the structure of the Wien filter 108 will be described. The Wien filter 108 is of a multipole lens type with an electromagnetic-field superposition structure, because the Wien filter 108 that satisfies the stigmatic condition is required to have both components of a uniform field and quadrupole fields. The minimum structure of the multipole lens type is a quadrupole structure, which, however, cannot produce an ideal uniform field and may cause a large distortion, resulting in the aberration of the primary electron beam. In view of these circumstances, there is a demand for a structure having more poles.

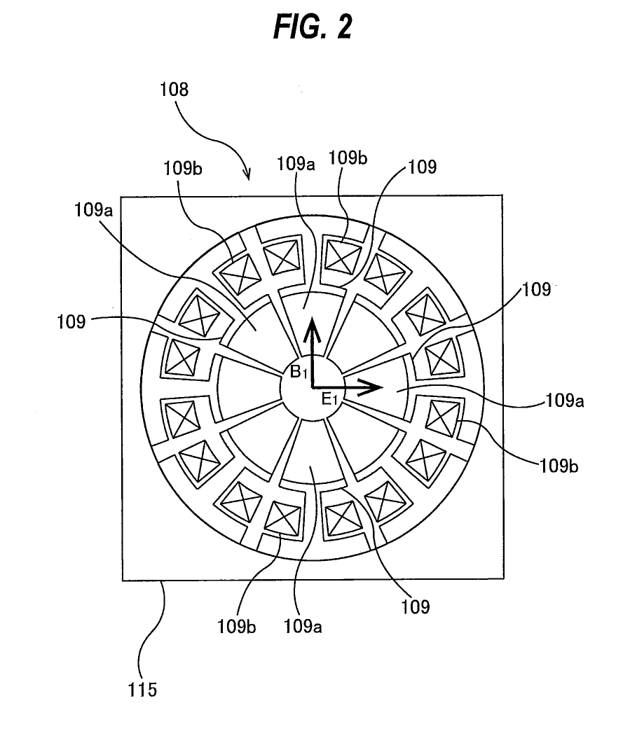

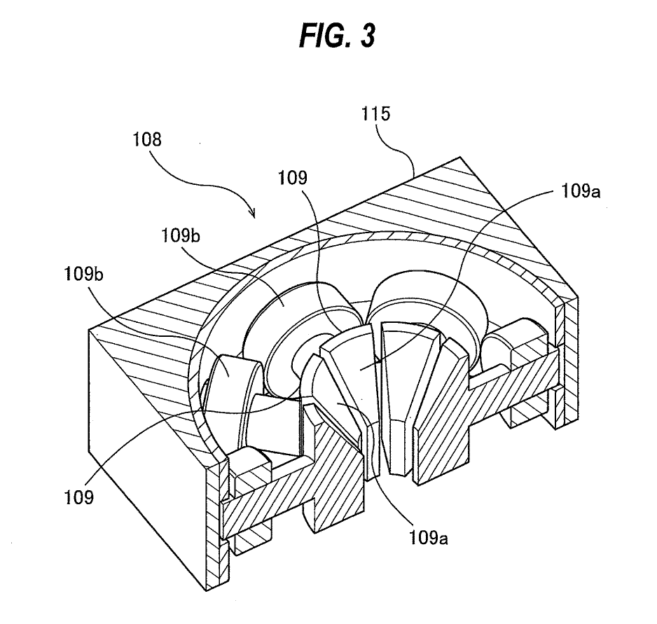

FIG. 2 is a schematic view of an octapole structure of the Wien filter 108 according to an embodiment of the present invention. FIG. 2 shows a plan view of the Wien filter 108 as viewed from a direction perpendicular to the beam axis. FIG. 3 is a cross-sectional perspective view of the Wien filter 108. Eight poles 109 are arranged around a central axis of the Wien filter 108 at regular intervals. These poles 109 include coils 109b, respectively. The eight poles 109 are surrounded by a shunt 115, which is grounded to have a ground potential. Each of the poles 109 has a center-side end, which has an upper surface constituted by a tapered surface 109a inclined downwardly toward the central axis of the Wien filter 108. The tapered surfaces 109a of the eight poles 109 are arranged around the central axis of the Wien filter 108 at regular intervals, thus forming a surface in a shape of truncated cone facing upward. The back-scattered electrons 104, emitted from the specimen 106, enter the Wien filter 108 from below, and pass out of the Wien filter 108 through its exit constituted by the tapered surfaces 109a.

Voltages Vn and excitations ATn (n=1,2, . . . , 8) are applied to the poles 109, respectively, to thereby produce a uniform field that satisfies the Wien condition and quadrupole fields for the stigmatic condition. All of the poles 109 work as electrodes and magnetic poles, and are therefore made of magnetic material, such as permalloy. It is possible to reduce aberration by increasing the number of poles to provide a ten-pole structure or twelve-pole structure. However, such structures entail difficulty in the aspect of mechanical precision, and further entail complicated control of a power source.

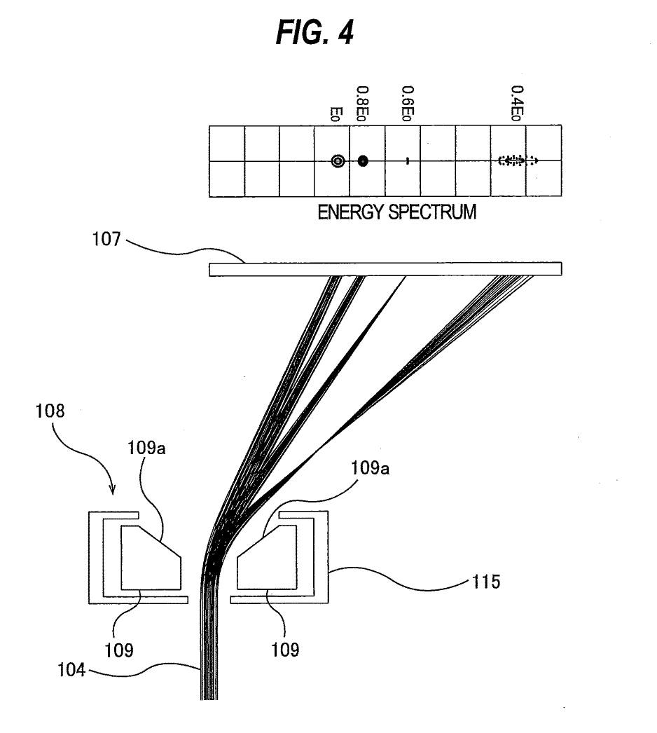

FIG. 4 shows a simulation result of the operation of the above-described Wien filter 108 having the octapole structure. In this simulation, it is assumed that the back-scattered electron beam 104 becomes a parallel beam after it has passed through the back-scattered electron diaphragm 110. The smaller the diameter of the back-scattered electron diaphragm 110, the more the energy resolution is improved. However, at the same time, the sensitivity is lowered. Therefore, the diameter of the back-scattered electron diaphragm 110 should be determined based on the finally required resolution and sensitivity. With respect to the crossover position of the primary electron beam, it is necessary to establish a condition for cancelling the energy dispersion on the surface of the specimen, as discussed previously. It is sufficient for a conventional Wien filter, having a symmetric shape about the beam axis, to form a crossover at the center of the filter. In contrast, it is necessary for the asymmetric Wien filter 108 of this embodiment to determine in advance a crossover position that can remove the energy dispersion on the specimen surface, or determine in advance a crossover position in an actual operation of the scanning electron microscope.

FIG. 4 shows the result of the simulation in which the voltages and the excitations for the poles 109 were set so as to satisfy the Wien condition and the stigmatic condition in the Wien filter 108. With only the electromagnetic poles 109 of the Wien filter 108, the distribution of the electromagnetic field spreads widely along the beam axis, thus interfering with other optical element. In order to prevent this, the shunt 115 as shown in FIG. 4 is provided. This shunt 115 is made of magnetic material, such as permalloy, which has a potential of zero. The shunt 115 exerts the same shielding action on both the electric field and the magnetic field produced by the poles 109 of the Wien filter 108.

The back-scattered electrons are deflected in accordance with the energies of the back-scattered electrons when they are passing through the Wien filter 108 having the tapered surfaces 109a. The array detector 107 detects the back-scattered electrons that have passed through the Wien filter 108. The detected back-scattered electrons are observed as an energy spectrum in which the back-scattered electrons are distributed in accordance with the energy, as shown in FIG. 4. Where E₀ represents the energy of the primary electron beam, energies E of the back-scattered electrons are distributed from 0 to E₀. According to the present embodiment, the array detector 107 can detect an energy width 0.6E₀ ranging from E₀ to 0.4E₀ at a time. Generally, an energy width of an electrostatic spherical analyzer or other type is about 0.1E₀ as described previously. According to the embodiment, the array detector 107 can measure a much wider energy range at a time, compared with the typical electrostatic spherical analyzer. The energy range in which the simultaneous detection can be achieved can be further broadened in accordance with the design of the tapered surfaces 109a of the electromagnetic poles 109 and the shunt 115.

With regard to the energy resolution, in FIG. 4, a direction of line focus for the energy of 0.6E₀ is perpendicular to a direction of the energy dispersion on a detection surface of the array detector 107. This characteristic of the line focus is maintained within an energy width of about ±0.05E₀ with its center on an energy value of 0.6E₀. However, the resolution of energies, which are apart from this energy width, is lowered because a beam is blurred in the dispersion direction. Generally, a focused surface of a beam, which has been dispersed in accordance with energy by the deflecting action of the Wien filter 108, becomes a curved surface. Therefore, there is only one energy that is focused on the flat detection surface. This action corresponds to field curvature aberration of a typical axisymmetric lens. However, this focus energy value can be shifted by controlling the strengths of the quadrupole fields produced by the Wien filter 108. Specifically, the lens actions in the x direction and the y direction can be changed by the quadrupole fields. Therefore, the original focus energy can be shifted by the change in the quadrupole fields, and a beam with a desired energy can be focused on the detection surface of the array detector 107.

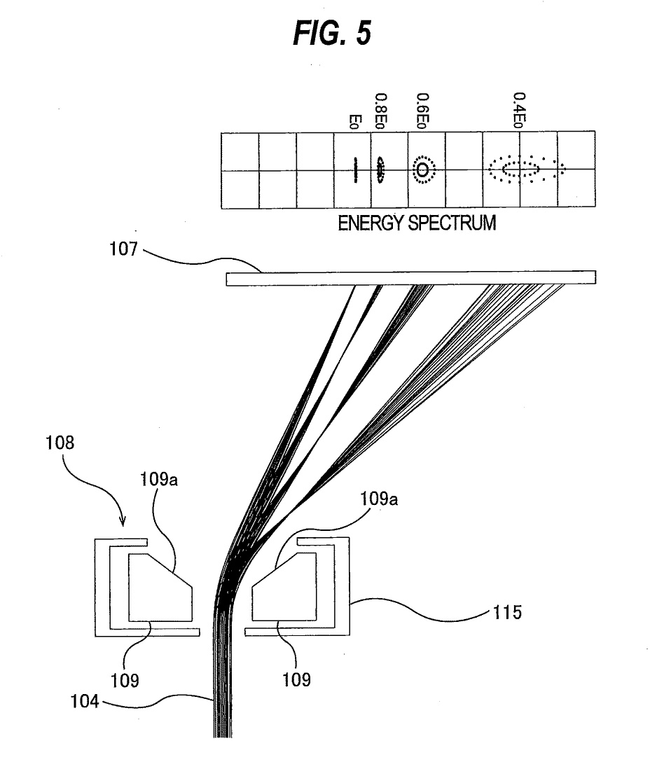

FIG. 5 shows such an example, and particularly shows a result of a simulation in which the focus energy coincides with E₀. In a case of forming an image of the back-scattered electrons in the energy range around E₀, this condition is the optimum. When the focus energy is shifted in this manner, the stigmatic condition for the primary electron beam is not satisfied. In order to correct this, an astigmatism correcting device 111 is disposed as shown in FIG. 1. This astigmatism correcting device 111 can cancel the astigmatism caused by the Wien filter 108. The astigmatism correcting device 111 can be arranged in any location within the optical system from the electron gun 101 to the specimen 106. The above-discussed operations using the quadrupole fields can establish an optimum energy resolution within a width of about 0.1E₀ at all times in conformity to the energy range in which an image of the back-scattered electrons is formed. Typically, the energy range in which an image of the back-scattered electrons is formed is sufficiently smaller than 0.1E₀. Therefore, an optimum energy resolution can be obtained at all times by this function.

In the simulations shown in FIG. 4 and FIG. 5, it is assumed that the back-scattered electron beam 104, which has passed through the back-scattered electron diaphragm 110, is a parallel beam. For this reason, blurring (or bokeh) ΔE of the line-focused energy at the detection surface of the array detector 107 is zero. Therefore, an actual energy resolution E/ΔE is determined depending on a position resolution of the array detector 107. However, the beam that has passed through the back-scattered electron diaphragm 110 may have an angular width depending on the configuration of the optical system from the specimen 106 to the back-scattered electron diaphragm 110. The energy resolution in such a case is determined by blurring (or bokeh) of the beam on the detection surface caused by the angular width of the beam, and by the position resolution of the array detector 107. This circumstance holds true for a conventional device using an analyzer of other type as well. For example, in the case of using the electrostatic spherical analyzer, the focusing condition for a parallel beam is satisfied at all times at an exit surface. However, because the energy width in which the simultaneous detection can be performed is about 0.1E₀, the electrostatic spherical analyzer has the same energy resolution as that of the above-described embodiment. In other words, by using the focus energy shifting mechanism according to the embodiment, the same energy resolution as a conventional device can be obtained.

The previous description of embodiments is provided to enable a person skilled in the art to make and use the present invention. Moreover, various modifications to these embodiments will be readily apparent to those skilled in the art, and the generic principles and specific examples defined herein may be applied to other embodiments. Therefore, the present invention is not intended to be limited to the embodiments described herein but is to be accorded the widest scope as defined by limitation of the claims.

What is claimed is:

1. A scanning electron microscope comprising:
an electron beam source for generating a primary electron beam;
an electron optical system configured to direct the primary electron beam to a specimen while focusing and deflecting the primary electron beam; and
an energy analyzing system capable of performing parallel detection of an energy spectrum of back-scattered electrons emitted from the specimen, the energy analyzing system including:
a Wien filter configured to separate the back-scattered electrons from a beam axis and analyze energies of the back-scattered electrons; and
an array detector configured to detect the back-scattered electrons that have passed through the Wien filter,
wherein the Wien filter includes a plurality of electromagnetic poles, center-side ends of the plurality of electromagnetic poles have tapered surfaces, respectively, and the tapered surfaces form an exit of the Wien filter through which the back-scattered electrons pass out.

2. The scanning electron microscope according to claim 1, wherein the Wien filter is configured to be able to change strengths of quadrupole fields comprising an electric field or a magnetic field, in order to optimize energy resolution in an energy range in which an image of the back-scattered electrons is formed.

3. The scanning electron microscope according to claim 1, further comprising:
an imaging device configured to create an image using only output signals of the array detector within a preselected energy range.
